(19) United States
(12) Patent Application Publication
(10) Pub. No.: US 2025/0006670 A1
(43) Pub. Date: Jan. 2, 2025

(54) ANTENNA MODULE WITH ANISOTROPIC HEXAGONAL BORON NITRIDE THERMAL INTERFACE

(71) Applicant: Nano and Advanced Materials Institute Limited, Hong Kong (HK)

(72) Inventors: Jinliang ZHAO, Hong Kong (HK); ChiHo KWOK, Hong Kong (HK); Yan LIU, Hong Kong (HK)

(21) Appl. No.: 18/754,206

(22) Filed: Jun. 26, 2024

Related U.S. Application Data
(60) Provisional application No. 63/510,634, filed on Jun. 28, 2023.

(51) Int. Cl. H01L 23/66; H01L 23/00; H01L 23/373

(52) U.S. Cl. CPC H01L 23/66; H01L 23/3737; H01L 23/3738; H01L 24/29; H01L 24/32; H01L 2223/6677; H01L 2224/2929; H01L 2224/29387; H01L 2224/32221; H01L 2924/14215

(57) ABSTRACT

A compact antenna module with integrated thermal management. The module includes at least one antenna and amplifier such as power amplifiers or low-noise amplifiers. An anisotropic thermal interface material is positioned such that it is in thermal communication with these components. The anisotropic thermal interface material includes plural aligned thermally anisotropic composite layers having a first thermal conductivity in a first direction and a second, larger thermal conductivity in a second direction and extend substantially parallel to each other in the first direction. The layers include hexagonal boron nitride (hBN) in a binder aligned in the second direction approximately perpendicular to the first direction such that x-y planes of the hBNalign in the second direction. In this manner, the thermal conductivity in the second direction is at least 13.5 W/mK, with a dielectric constant of less than 4, and a loss tangent of less than 0.007.

### CROSS-REFERENCE TO RELATED APPLICATIONS

The present application claims priority from U.S. provisional patent application Ser. No. 63/510,634 filed Jun. 28, 2023, and the disclosure of which is incorporated herein by reference in its entirety.

### FIELD OF THE INVENTION

The invention relates to antenna modules, in general, an, more particularly to 5G antenna modules with anisotropic hexagonal boron nitride thermal interface materials.

### BACKGROUND OF THE INVENTION

The antenna system in a 5G module plays a vital role in transmitting and receiving signals with minimal delay. Antenna design parameters, such as gain, beamforming, and directivity, need to be optimized to ensure efficient signal propagation and reception. Additionally, the use of advanced antenna technologies like massive MIMO (Multiple Input Multiple Output) and beamforming can help improve spatial multiplexing and reduce interference, ultimately enhancing the system's capacity and reducing latency.

Antenna performance may be seriously impacted by temperature variations, which may occur due to environmental factors or the heat generated internally within the module. One significant effect is the shift in the antenna's resonance frequency with increasing temperatures. As the temperature rises, the physical properties of the antenna and its components, such as the length and permittivity, can change, leading to a decrease in the resonance frequency. Low network latency is a critical requirement in 5G communication systems as it enables real-time and interactive applications such as autonomous vehicles, remote surgery, and augmented reality. A decrease in resonance frequency and increase in return loss can result in a mismatch between the antenna's designed frequency and the actual operating frequency resulting in decreased antenna efficiency and degraded signal transmission. As a result, network latency will be negatively impacted. FIG. 7 depicts the return loss for an antenna. Return loss is defined as the amount of power returned or reflected at the antenna power input port. In antenna design, lower reflection loss is more desirable. The wave trough of return loss points to the antenna resonant frequency. The temperature can affect the antenna resonant frequency; if the temperature increases, the resonant frequency will shift to lower frequency. In FIG. 7, as the temperature increases from 27° C. to 117° C., the wave trough (V) is shifted from 2.95 GHz to 2.9 GHz which is a large shift that will affect the overall communication system.

Additionally, 5G antenna modules include several heat-generating components that are packaged close together, making thermal management more challenging. In particular, 5G antenna modules include power amplifiers for amplifying the received RF signals to the desired power level. Power amplifiers are known to produce significant amounts of heat due to the power amplification process. The higher the power level, the more heat is generated. Efficient thermal management is crucial to dissipate the heat generated by power amplifiers to maintain their performance and prevent overheating.

Additionally, transceiver integrated circuits (ICs) in 5G antenna modules handle the modulation and demodulation of the wireless signals. These ICs can generate heat during signal processing, especially when operating at higher frequencies and data rates. Adequate thermal management is necessary to maintain the optimal performance and reliability of these ICs. Further baseband processors handle the digital processing of signals in 5G antenna modules. They perform tasks such as data encoding, decoding, and signal synchronization. These processors can consume significant power and generate heat during their operation. Effective heat dissipation mechanisms are required to prevent thermal issues that can impact the performance and longevity of the baseband processors.

Switches and filters are essential components in 5G antenna modules for signal routing, beamforming, and frequency selection. Depending on the design and complexity of the module, these components can consume power and generate heat. Proper thermal management techniques need to be implemented to minimize the heat accumulation and maintain their performance. Finally, 5G antenna modules may also include control and monitoring circuits responsible for managing the module's operation, including power management, signal monitoring, and system diagnostics. While these circuits might not be the primary heat generators, they can still contribute to the overall heat dissipation requirements of the module.

Although 5G antenna modules can vary depending on the specific module design, power requirements, and operational conditions, effective thermal management strategies, including the use of appropriate thermal interface materials, heat sinks, and cooling mechanisms, are essential to ensure proper heat dissipation and prevent performance degradation or damage to the components within the module. However, there are certain challenges associated with existing thermal interface materials, particularly concerning the dielectric constant (Dk) and loss tangent (Df), as well as issues with metals at high frequencies, specifically above 20 GHz.

Thermal interface materials often consist of materials that have a relatively high Dk and Df. The dielectric constant represents the ability of a material to store electrical energy, while the loss tangent reflects the dissipation of energy as heat. At high frequencies, greater than 20 GHz, the wavelength of the electromagnetic waves becomes smaller, and the parasitic capacitance and inductance effects of the thermal interface material become more significant. This can lead to increased signal losses, impedance mismatches, and reduced antenna performance.

Many existing thermal interface materials utilize metal particles or fillers to enhance their thermal conductivity. However, metals can exhibit higher electrical losses, especially at higher frequencies. At frequencies above 20 GHz, metals tend to have increased skin depth, meaning that the electrical current is concentrated near the material's surface. This can cause higher resistive losses and signal attenuation, leading to heat buildup and reduced overall system efficiency.

Thermal interface materials are responsible for transferring heat from the power amplifier to the heat sink or chassis. However, the aforementioned problems with Dk, Df, and metals can result in poor thermal conductivity and increased thermal resistance. This leads to heat buildup within the antenna module, negatively impacting the system's reliability, efficiency, and potentially causing premature failure of components.

Overall, ensuring low network latency by proper thermal management to minimize temperature variation effects are needed to optimizing antenna systems for 5G modules. By addressing these factors, the performance, reliability, and efficiency of the 5G communication system can be improved, enabling seamless and responsive connectivity in various applications. The present invention addresses this need.

### SUMMARY OF THE INVENTION

It is an objective of the present invention to provide a compact antenna module to solve the aforementioned technical problems.

In accordance with a first aspect of the present invention, a compact antenna module is provided.

The present invention provides antenna modules with thermal interface materials (TIM) made from hexagonal boron nitride (h-BN). Hexagonal boron nitride is a two-dimensional material with excellent thermal conductivity along the basal plane, making it attractive for formation of anisotropic thermal interface materials. The unique structure of h-BN, consisting of alternating boron and nitrogen atoms arranged in a hexagonal lattice, allows for efficient heat transfer through phonon transport. The thermal conductivity of h-BN can exceed 500 W/mK in the basal plane. Further, h-BN has a low dielectric constant on the order of approximately 3.5 to 4 along with a low dielectric loss tangent of 0.0012.

In the context of 5G antenna modules, anisotropic h-BN as a TIM enhances heat dissipation and improve thermal management while preventing signal loss and latency caused by the high Dk and Df of typical thermal interface materials. By incorporating h-BN as a thin layer between the heat-generating components (such as power amplifiers) and the heat sink or chassis, the present invention minimizes thermal resistance and facilitates efficient heat transfer. This, in turn, can prevent heat buildup, maintain lower operating temperatures, and preserve the performance and reliability of the antenna module.

Additionally, anisotropic h-BN has other desirable properties for TIM applications, including high electrical resistivity, chemical stability, and low interfacial thermal resistance with various materials. These characteristics make it a suitable choice for addressing both thermal and electrical considerations in 5G antenna modules.

In one aspect, the present invention provides a compact antenna module with integrated thermal management. The module includes at least one antenna or antenna array along with at least one amplifier such as power amplifiers or low-noise amplifiers. An anisotropic thermal interface material is positioned such that it is in thermal communication with the at least one antenna or antenna array and with the at least one amplifier. The anisotropic thermal interface material includes plural aligned thermally anisotropic composite layers having a first thermal conductivity in a first direction and a second, larger thermal conductivity in a second direction and the aligned thermally anisotropic composite layers extend substantially parallel to each other in the first direction.

Each of the thermally anisotropic composite layers includes hexagonal boron nitride (hBN) in a binder. The hBN is aligned in the second direction approximately perpendicular to the first direction such that x-y planes of the hBN align in the second direction having the second, larger thermal conductivity. In this manner, the thermal conductivity in the second direction is at least 13.5 W/mK, with a dielectric constant of less than 4, and a loss tangent of less than 0.007. The thermally anisotropic conductive composite layers are adhered to adjacent thermally anisotropic composite layers to create a laminated anisotropic composite thermal interface device.

In one aspect the anisotropic thermal interface material binder is a polymer binder.

Each thermally anisotropic composite layer includes 60 to 95 wt %, hBN and 5 to 40 wt % of binder, which, in one embodiment, may be 70 to 75 wt %, hBN.

In one aspect, the polymer binder is selected from polysiloxanes, thermoplastic elastomers, polyisoprene, or polybutadiene.

In one aspect, a thickness of the anisotropic thermal interface material is approximately 0.1 to 0.6 mm.

In one aspect, the anisotropic thermal interface material has a dielectric breakdown voltage of at least approximately 13 kV/mm.

In one aspect, the anisotropic thermal interface material is thermally coupled to a heat sink or heat exchanger to further enhance thermal management.

In another aspect, the module further includes a passive or active cooling mechanism in thermal communication with the anisotropic thermal interface material to dissipate heat more effectively.

In one aspect, the anisotropic thermal interface material is flexible, allowing conformal contact with irregular surfaces of the antenna, antenna array, amplifier, and passive components.

In one aspect, the anisotropic thermal interface material includes a layer of thermally conductive adhesive on one or both sides to enhance thermal contact with the antenna, antenna array, amplifier, and passive components.

In one aspect, the anisotropic thermal interface material is capable of withstanding operating temperatures ranging from −40° C. to 150° C. without significant degradation of thermal properties.

In another aspect, the at least one antenna or antenna array is integrated into a printed circuit board (PCB) and the anisotropic thermal interface material is positioned between the PCB and the amplifier.

In another aspect, the anisotropic thermal interface material further includes a protective outer layer or coating layer to provide environmental protection and enhance durability.

In one aspect, the anisotropic thermal interface material includes a layer of thermally conductive adhesive on one or both sides to enhance thermal contact with the antenna or antenna array and the amplifier.

In one aspect, the antenna or antenna array operates in a frequency range selected from VHF, UHF, L-band, S-band, C-band, X-band, Ku-band, K-band, or Ka-band.

In one aspect, the anisotropic thermal interface material has a thermal resistance of less than 0.5° C./W in the second direction.

In one aspect, the hBN is in a form selected from a flake, a fiber or a platelet form.

### BRIEF DESCRIPTION OF THE DRAWINGS

Embodiments of the invention are described in more details hereinafter with reference to the drawings, in which:

FIG. 1 an antenna module according to an embodiment;

FIG. 2 depicts a manufacturing technique for thermal interface materials for the antenna modules of the present invention;

FIG. 3 depicts properties of a thermal interface material for the antenna modules of the present invention;

FIGS. 4A-4B show dielectric permittivity vs. filler content for hexagonal boron nitride (FIG. 4A) and dielectric loss vs. filler content for hexagonal boron nitride (FIG. 4B);

FIGS. 5A-5B depicts results of thermal conductivity tests, in which FIG. 5A depicts the correlation between impedance and thickness and FIG. 5B shows the vertical alignment of hBN via SEM;

FIGS. 6A-6B show Dk (FIG. 6A) and Df (FIG. 6B) at high frequency via a split cylinder resonator; and

FIG. 7 (prior art) depicts return loss vs. frequency.

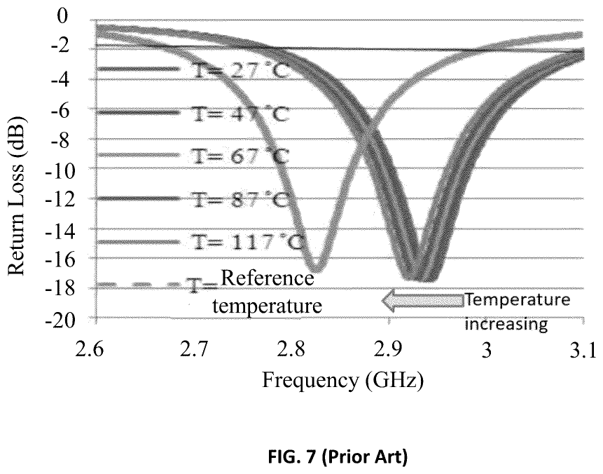

### DETAILED DESCRIPTION

In the following description, compact antenna modules and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

In accordance with a first aspect of the present invention, a compact antenna module is introduced.

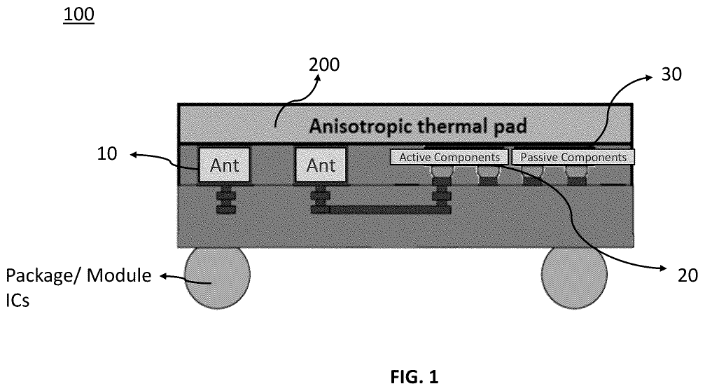

Turning to the drawings in detail, FIG. 1 depicts an antenna module with integrated thermal management according to the present invention. Antenna module 100 includes an antenna or antenna array 10, such as a MIMO (multiple input/multiple output) antenna used in 4G and 5G communications. The antenna module 100 requires several active and passive components to manage the power signals sent to and received from antenna 10. These may include amplifier such as power amplifiers, which generate a considerable amount of heat in order to amplify antenna signals. Low noise amplifiers may also be included in the active components 20. Other components, such as passive components 30 (e.g., filters and switches) are also included in the antennal module 100. Other components such as transceiver integrated circuits (ICs) may also be included in the antenna modules for modulating and demodulating wireless transmission.

A thermal interface material such as anisotropic thermal pad 200 is positioned in thermal communication with the antenna/antenna array 10, the active components 20 and, optionally, the passive components 30 (which generate less heat). By “thermal communication” it is meant that heat generated from the various components is transferred to the thermal interface material 200, either directly through direct contact, or through an intermediate component such as a contact enhancing paste, or through a third, heat-transferring component. Although not shown in FIG. 1, the anisotropic thermal interface material 200 may itself be in thermal communication with a heat sink, heat exchanger, or other passive or active cooling component.

The thermal interface material 200 includes individual layers of compacted hexagonal boron nitride (hBN) that are carefully fabricated into a thermally anisotropic composite layer structure to maximize the anisotropic heat transfer from the antenna components. The anisotropic thermal interface material includes plural aligned thermally anisotropic composite layers having a first thermal conductivity in a first direction and a second, larger thermal conductivity in a second direction and the aligned thermally anisotropic composite layers extend substantially parallel to each other in the first direction.

In particular, each of the thermally anisotropic composite layers includes hBN in a binder (for example, a polymer binder). The hBN is aligned in the second direction approximately perpendicular to the first direction such that x-y planes of the hBN align in the second direction having the second, larger thermal conductivity. In this manner, the thermal conductivity in the second direction is at least 13.5 W/mK, with a dielectric constant of less than 4, and a loss tangent of less than 0.007. The thermally anisotropic composite layers are adhered to adjacent thermally anisotropic composite layers to create the laminated anisotropic composite thermal interface device.

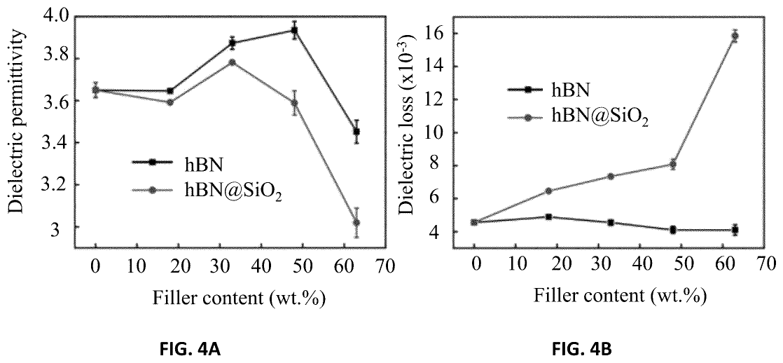

In one embodiment, the polymer matrix may be selected from polymers such as polysiloxanes, thermoplastic elastomers, polyisoprene, polybutadiene, or other suitable polymers. As shown in FIGS. 4A-4B, the preferred weight ratio is 5 to 40 wt % of the polymer matrix and 60 to 95 wt % of hBN flakes, with 70 to 75 wt. % of hBN flakes being a particular embodiment. This composition ensures an optimal balance of thermal conductivity and mechanical properties.

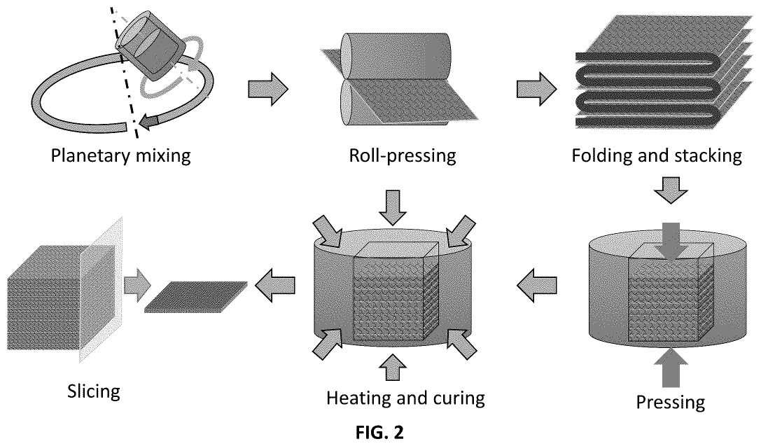

To create the thermally anisotropic layers having the structure that provides the thermal conductivity numbers cited above, an alignment and bonding process is performed on the hBN as seen in FIG. 2. The hBN are dispersed in the selected polymer binder or mixture of binders, optionally with a solvent to control the rheology. Various dispersion techniques, such as ultrasonication, shear mixing, or the planetary mixing of FIG. 2 can be employed to ensure proper dispersion and prevent agglomeration of the h-BN. In particular, dispersion techniques that minimize h-BN breakage will increase the thermal conduction properties of the final material.

Optionally, if a solvent is used, a controlled drying step (not shown) may be used to remove solvent in a manner to increase the alignment of the mixed hBN/binder layer. The alignment of hBN permits the formed layer to possess the anisotropic thermal transfer properties. since by aligning the “two-dimensional” layers parallel to the heat flow direction enables efficient heat conduction along the basal plane of h-BN, which exhibits significantly higher thermal conductivity compared to the through-plane direction. This anisotropic property allows for preferential heat transfer and helps mitigate thermal resistance across the interface.

Following roll-pressing, multiple thermal conductive composite films are stacked in parallel; the layers are bound with an interlayer bonding of the polymer matrix or another polymeric material. In this configuration, they are subject to further heat and compression to form a compressed stack.

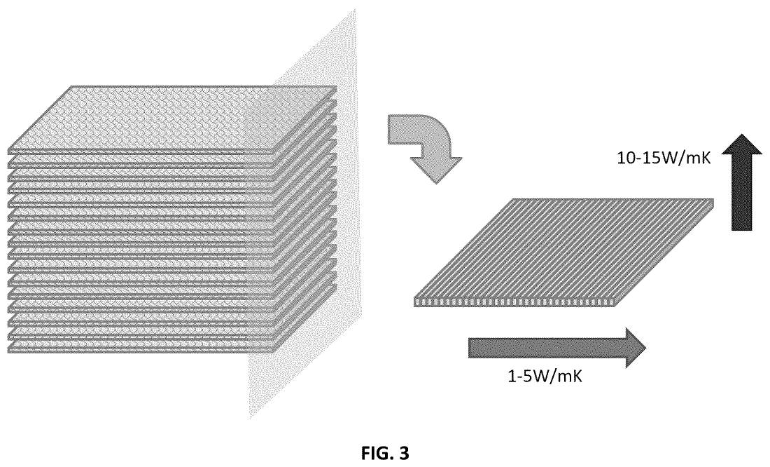

The compressed stack is then subjected to an ultrasonic cutter, which slices the bound films in a direction perpendicular to the film plane direction, as seen in FIG. 3. This process yields individual thermal interface material pads with a selected thickness of 0.1 to 0.6 mm (although other thicknesses may be selected depending upon the final antenna module configuration).

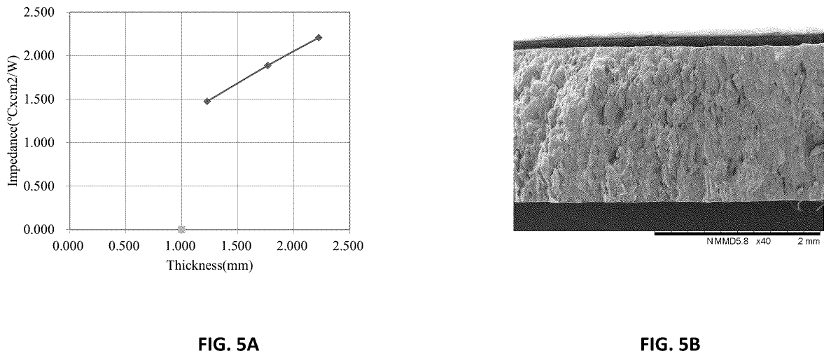

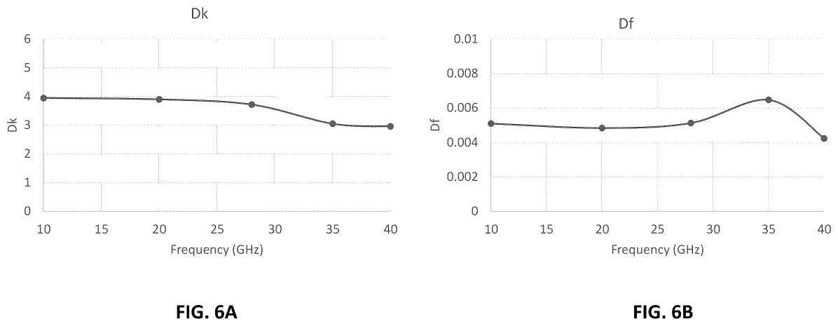

The thermal interface material used in the antenna modules of the present invention exhibit several desirable properties for high-frequency signal transmission and thermal management. It has a high through-plane thermal conductivity of at least 13.5 W/mK, as measured by the ASTM 5470-06 standard; thermal conductivity test results are depicted in FIGS. 5A-5B and Table 1, in which FIG. 5A depicts the correlation between impedance and thickness and FIG. 5B shows the vertical alignment of hBN via SEM. Additionally, it possesses a low dielectric constant (Dk) of less than 4 and a low dielectric loss tangent (Df) of less than 0.007 as seen in FIGS. 6A-6B. These properties minimize signal loss, reduce signal latency, and enhance system stability in high-frequency applications.

TABLE 1
Thermal Conductivity test results via ASTM 5470-06

| | Thermal | Imp | Thickness |
|---|---|---|---|
| Sample | conductivity (W/mK) | (° C. cm²/W) | (mm) |
| 1 | 8.33 | 1.474 | 1.227 |
| 2 | 9.37 | 1.885 | 1.767 |
| 3 | 10.08 | 2.206 | 2.223 |

| | |
|---|---|
| Reported Tc | 13.58 W/mK |

Furthermore, it demonstrates a dielectric breakdown voltage of over 13 kV/mm, providing electrical insulation and preventing any electrical interference. The results are detailed in Table 2.

TABLE 2
Dielectric breakdown voltage

| | | Breakdown voltage | Breakdown Voltage |
|---|---|---|---|
| hBN films | Thickness (μm) | AC/DC (kV) | AC/DC (kV/mm) |
| 1 | 350 | 5/6 | 14.3/17.1 |
| 2 | 350 | 5/6 | 14.3/17.1 |
| 3 | 365 | 5/6 | 13.7/16.4 |
| 4 | 350 | 5/6 | 14.3/17.1 |

In some embodiments, the compact antenna module employs an anisotropic thermal interface material, which is thermally coupled to a heat sink or heat exchanger to enhance thermal management. This coupling ensures efficient dissipation of heat generated by the antenna, antenna array, and amplifiers, thus maintaining optimal operating temperatures and prolonging the life of the components.

To further improve thermal management, the antenna module incorporates a passive or active cooling mechanism that works in tandem with the anisotropic thermal interface material. This combination allows for more effective heat dissipation, preventing overheating and ensuring consistent performance even under high-power conditions.

The anisotropic thermal interface material used in the module is highly flexible, enabling it to conform to the irregular surfaces of the antenna, antenna array, amplifier, and passive components. This flexibility is crucial for maintaining good thermal contact across all components, thereby enhancing the overall thermal conductivity of the system. Additionally, the thermal interface material includes a layer of thermally conductive adhesive on one or both sides to enhance thermal contact with the antenna, antenna array, amplifier, and passive components. This adhesive layer further improves thermal contact, ensuring that heat is efficiently transferred away from the components. Optionally, the anisotropic thermal interface material may include a layer of thermally conductive adhesive on one or both sides to enhance thermal contact with the antenna or antenna array and the amplifier.

In another embodiment, the anisotropic thermal interface material includes a layer of thermally conductive adhesive on one or both sides to enhance thermal contact with the antenna or antenna array and the amplifier.

One of the significant advantages of the anisotropic thermal interface material is its ability to withstand a wide range of operating temperatures, from −40° C. to 150° C. This resilience ensures that the material maintains its thermal properties and structural integrity even under extreme temperature conditions, making it suitable for various applications and environments.

Furthermore, the antenna module features an integration where the at least one antenna or antenna array is embedded into a printed circuit board (PCB). The anisotropic thermal interface material is strategically positioned between the PCB and the amplifier, ensuring that heat generated by the amplifier is effectively transferred away from the PCB, preventing potential damage and maintaining signal integrity.

To enhance durability and provide environmental protection, the compact antenna module includes a protective outer layer or coating over the anisotropic thermal interface material. This layer safeguards the thermal interface material from environmental factors such as moisture, dust, and mechanical wear, thereby extending the lifespan of the module and ensuring reliable performance over time.

In some embodiments, the antenna or antenna array operates in a frequency range selected from VHF, UHF, L-band, S-band, C-band, X-band, Ku-band, K-band, or Ka-band.

In some embodiments, the anisotropic thermal interface material has a thermal resistance of less than 0.5° C./W in the second direction.

In some embodiments, the hBN is in a form selected from a flake, a fiber or a platelet form.

Overall, the detailed description of the compact antenna module with integrated thermal management emphasizes the innovative use of anisotropic thermal interface materials and advanced cooling mechanisms to achieve superior thermal performance, flexibility, and durability in a compact and efficient design.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to 0.05%. The term “substantially coplanar” can refer to two surfaces within micrometers of lying along a same plane, such as within 40 m, within 30 m, within 20 m, within 10 m, or within 1 m of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. A compact antenna module with integrated thermal management, comprising:
at least one antenna or antenna array;
at least one amplifier selected from power amplifiers or low-noise amplifiers;
an anisotropic thermal interface material in thermal communication with the at least one antenna or antenna array and with the at least one amplifier, the anisotropic thermal interface material including:
plural aligned thermally anisotropic composite layers having a first thermal conductivity in a first direction and a second, larger thermal conductivity in a second direction, the aligned thermally anisotropic composite layers extending substantially parallel to each other in the first direction;
each of the thermally anisotropic composite layers including hexagonal boron nitride (hBN) in a binder, the hBN being aligned in the second direction approximately perpendicular to the first direction such that x-y planes of the hBN align in the second direction having the second, larger thermal conductivity, the thermal conductivity in the second direction being at least 13.5 W/mK, the boron nitride composite layers having a dielectric constant of less than 4, and a loss tangent of less than 0.007, the thermally anisotropic conductive composite layers being adhered to adjacent thermally anisotropic composite layers to create a laminated anisotropic composite thermal interface device.

2. The compact antenna module of claim 1, wherein the anisotropic thermal interface material binder is a polymer binder.

3. The compact antenna module of claim 1, wherein each thermally anisotropic composite layer includes 60 to 95 wt % of hBN and 5 to 40 wt % of binder.

4. The compact antenna module of claim 3, wherein each thermally anisotropic composite layer includes 70 to 75 wt % hBN and 25 to 30 wt % of binder.

5. The compact antenna module of claim 2, wherein the polymer binder is selected from polysiloxanes, thermoplastic elastomers, polyisoprene, or polybutadiene.

6. The compact antenna module of claim 1, wherein a thickness of the anisotropic thermal interface material is approximately 0.1 to 0.6 mm.

7. The compact antenna module of claim 1, wherein the anisotropic thermal interface material has a dielectric breakdown voltage of at least approximately 13 kV/mm.

8. The compact antenna module of claim 1, wherein the anisotropic thermal interface material is thermally coupled to a heat sink or heat exchanger to further enhance thermal management.

9. The compact antenna module of claim 1, further comprising a passive or active cooling mechanism in thermal communication with the anisotropic thermal interface material to dissipate heat more effectively.

10. The compact antenna module of claim 1, wherein the anisotropic thermal interface material is flexible, allowing conformal contact with irregular surfaces of the antenna, antenna array, amplifier, and passive components.

11. The compact antenna module of claim 10, wherein the anisotropic thermal interface material includes a layer of thermally conductive adhesive on one or both sides to enhance thermal contact with the antenna, antenna array, amplifier, and passive components.

12. The compact antenna module of claim 1, wherein the anisotropic thermal interface material is capable of withstanding operating temperatures ranging from −40° C. to 150° C. without significant degradation of thermal properties.

13. The compact antenna module of claim 1, wherein the at least one antenna or antenna array is integrated into a printed circuit board (PCB) and the anisotropic thermal interface material is positioned between the PCB and the amplifier.

14. The compact antenna module of claim 1, further comprising a protective outer layer or coating over the anisotropic thermal interface material to provide environmental protection and enhance durability.

15. The compact antenna module of claim 1, wherein the anisotropic thermal interface material includes a layer of thermally conductive adhesive on one or both sides to enhance thermal contact with the antenna or antenna array and the amplifier.

16. The compact antenna module of claim 1, wherein the antenna or antenna array operates in a frequency range selected from VHF, UHF, L-band, S-band, C-band, X-band, Ku-band, K-band, or Ka-band.

17. The compact antenna module of claim 1, wherein the anisotropic thermal interface material has a thermal resistance of less than 0.5° C./W in the second direction.

18. The compact antenna module of claim 1, wherein the hBN is in a form selected from a flake, a fiber or a platelet form.
